(19) United States
(12) Patent Application Publication
(10) Pub. No.: US 2013/0045582 A1
(43) Pub. Date: Feb. 21, 2013

(54) CAPACITOR INSULATING FILM, METHOD OF FORMING THE SAME, CAPACITOR AND SEMICONDUCTOR DEVICE USING THE CAPACITOR INSULATING FILM

(71) Applicant: Elpida Memory, Inc., Tokyo (JP)

(72) Inventors: Takakazu KIYOMURA, Tokyo (JP); Toshiyuki HIROTA, Tokyo (JP)

(73) Assignee: ELPIDA MEMORY, INC., Tokyo (JP)

(21) Appl. No.: 13/660,537

(22) Filed: Oct. 25, 2012

Related U.S. Application Data
(62) Division of application No. 12/548,010, filed on Aug. 26, 2009.

(30) Foreign Application Priority Data
Aug. 29, 2008 (JP) 2008-221491

(51) Int. Cl. H01L 21/02

(52) U.S. Cl. 438/396; 438/381; 257/E21.008

(57) ABSTRACT

A capacitor insulating film may include, but is not limited to, strontium, titanium, and oxygen. The capacitor insulating film has a ratio of a spectrum intensity of (200) crystal face of the capacitor insulating film to a spectrum intensity of (111) crystal face of the capacitor insulating film in the range of 1.0 to 2.3. Each of the spectrum intensities of (200) crystal face and (111) crystal face is measured by an X-ray diffraction method.

### CROSS REFERENCE TO RELATED APPLICATIONS

This application is a Divisional of U.S. patent application Ser. No. 12/548,010, filed Aug. 26, 2009, which claims priority to Japanese Patent Application No. 2008-221491, filed Aug. 29, 2008, the contents of all of which are incorporated herein by reference.

### BACKGROUND OF THE INVENTION

1. Field of the Invention

The present invention relates to a capacitor insulating film of a semiconductor device such as a Dynamic Random Access Memory, hereinafter referred to as a DRAM, and a method of forming the same.

Priority is claimed on Japanese Patent Application No. 2008-221491, filed Aug. 29, 2008, the content of which is incorporated herein by reference.

2. Description of the Related Art

In recent years, the size of a capacitor of a memory cell has been decreasing due to the advancement of minute processing techniques and high integration techniques of a DRAM. It has been difficult to acquire a sufficient capacity of the capacitor. The use of a capacitor insulating film of high dielectric constant in the capacitor is being developed. For example, Japanese Unexamined Patent Application, First Publications, No. 2004-146559 addresses that an SrTiOx film, where x is a positive number and hereinafter referred to as an STO film, is a powerful candidate for the capacitor insulating film.

The STO film has high dielectric constant when the thickness of the STO film is about 100 nm. But the dielectric constant of the STO film dramatically decreases if the STO film is thinned. It is difficult to make the STO film thick and at the same time make the capacity of the capacitor large.

Japanese Unexamined Patent Application, First Publications, No. 2004-146559 discloses a method of forming the STO film of high dielectric constant in the range of 130 to 170. The method is that a 20-nm-thick amorphous STO film is formed on a bottom electrode of polycrystalline Ru, and the amorphous STO film is treated with heat at in the range of 500° C. to 650° C. in an inert gas atmosphere. The amorphous STO film is formed on the bottom electrode at a high temperature of 420° C. by a Chemical Vapor Deposition method, hereinafter referred to as a CVD method. The high temperature causes a leakage by a damage of the bottom electrode.

In recent years, the thickness of the capacitor insulating film needs to be thinner when used in the DRAM of high capacity. The thickness of the capacitor insulating film needs to be about 10 nm in a generation of 40-nm-class process technology. When the capacitor insulating film is so thin, the dielectric constant of the capacitor insulating film decreases significantly, so further improvement is needed.

### SUMMARY

A capacitor insulating film may include, but is not limited to, strontium, titanium, and oxygen. The capacitor insulating film has a ratio of a spectrum intensity of (200) crystal face of the capacitor insulating film to a spectrum intensity of (111) crystal face of the capacitor insulating film in the range of 1.0 to 2.3. Each of the spectrum intensities of (200) crystal face and (111) crystal face is measured by an X-ray diffraction method.

A capacitor may include, but is not limited to, two electrodes, a capacitor insulating film disposed between the two electrodes. The capacitor insulating film may include, but is not limited to, strontium, titanium, and oxygen. The capacitor insulating film has a ratio of a spectrum intensity of (200) crystal face of the capacitor insulating film to a spectrum intensity of (111) crystal face of the capacitor insulating film in the range of 1.0 to 2.3. Each of the spectrum intensities of (200) crystal face and (111) crystal face is measured by an X-ray diffraction method.

A semiconductor device may include, but is not limited to, a capacitor. The capacitor may include, but is not limited to, two electrodes, a capacitor insulating film disposed between the two electrodes. The capacitor insulating film may include, but is not limited to, strontium, titanium, and oxygen. The capacitor insulating film has a ratio of a spectrum intensity of (200) crystal face of the capacitor insulating film to a spectrum intensity of (111) crystal face of the capacitor insulating film in the range of 1.0 to 2.3. Each of the spectrum intensities of (200) crystal face and (111) crystal face is measured by an X-ray diffraction method.

A method of fabricating a capacitor insulating film, the method may include, but is not limited to, forming a titanium oxide film, forming an amorphous strontium titanate film on the titanium oxide film, and forming a crystallized film that contains strontium, titanium and oxygen by carrying out a heat treatment in an inert gas atmosphere. The crystallized film has a crystal structure that a ratio of a spectrum intensity of (200) crystal face of the capacitor insulating film to a spectrum intensity of (111) crystal face of the capacitor insulating film is in the range of 1.0 to 2.3. Each of the spectrum intensities of (200) crystal face and (111) crystal face is measured by an X-ray diffraction method.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a capacitor in accordance with a first preferred embodiment of the present invention;

FIG. 2 is a flow chart illustrating processes of forming the capacitor of FIG. 1;

FIG. 3A is a fragmentary cross sectional elevation view illustrating the capacitor of a first forming process of FIG. 2;

FIG. 3B is a fragmentary cross sectional elevation view illustrating the capacitor of a second forming process of FIG. 2;

FIG. 3C is a fragmentary cross sectional elevation view illustrating the capacitor of a third forming process of FIG. 2;

FIG. 4 is a chart indicating the relationship between a spectrum intensity ratio (200)/(111) of the STO film and thickness of the titanium oxide (TiOx) film formed in the process S2 of FIG. 2, where the spectrum intensity ratio (200)/(111) of the STO film is a ratio of a spectrum intensity of (200) crystal face of the STO film to a spectrum intensity of (111) crystal face of the STO film, and each of the spectrum intensities of (200) crystal face and (111) crystal face is measured by an X-ray diffraction method;

FIG. 5 is a chart indicating the relationship between the dielectric constant of the formed STO film and the thickness of the titanium oxide (TiOx) film;

FIG. 6 is a chart indicating the relationship between the dielectric constant of the formed STO film and the spectrum intensity ratio (200)/(111) of the STO film;

FIG. 7 is a chart indicating the relationship between the dielectric constant of the formed STO film and the thickness of the STO film;

FIG. 8A is a fragmentary vertical cross-sectional view illustrating the capacitor of a circular cylindrical shape that is a pillar shape using the capacitor insulating film of the present invention;

FIG. 8B is a fragmentary vertical cross-sectional view illustrating the capacitor of a hollow cylinder shape that is a cylinder shape using the capacitor insulating film of the present invention;

FIG. 9 is a fragmentary plain view illustrating the memory cell of the DRAM;

FIG. 10 is a cross sectional view illustrating the memory cell of the completed DRAM using the capacitor insulating film of the present invention; and

FIG. 11 is a chart indicating the relationship between the thickness of the capacitor insulating film and the leakage value and the capacity value of the capacitor using the capacitor insulating film of the present invention.

### DETAILED DESCRIPTION OF THE PREFERRED EMBODIMENTS

The present inventors pursuit the cause of decreasing dielectric constant of the STO film with the reduction in thickness of the STO film, and find that (111) crystal face of the STO film is easily oriented and that the orientation of the (111) crystal face causes the decrease of the dielectric constant of the STO film.

The present inventors find that the (111) crystal face of the STO film becomes easily oriented with the reduction in thickness of the STO film, and that the easiness of the orientation of the (111) crystal face of the STO film causes the decrease of the dielectric constant of the STO film.

Even if the thickness of the STO film is reduced to 10 nm thick, the decrease of the dielectric constant of the STO film is prevented by forming the STO film with suppressing the orientation of the (111) crystal face of the STO film.

A capacitor insulating film of the invention is formed so that a spectrum intensity ratio (200)/(111) of the STO film is in the range of 1.0 to 2.3, where the spectrum intensity ratio (200)/(111) of the STO film is a ratio of a spectrum intensity of (200) crystal face of the STO film to a spectrum intensity of (111) crystal face of the STO film and each of the spectrum intensities of the (200) crystal face and (111) crystal face is measured by an X-ray diffraction method.

The STO film of the invention is formed by forming an amorphous STO film on a titanium oxide (TiOx) film and treating the amorphous STO film with heat in an inert gas atmosphere to be a crystal STO film.

Capacitor with large capacity can be fabricated easily by the method of the invention. A semiconductor memory device of high performance that has an excellent refresh characteristic can be fabricated easily by forming a memory cell of a DRAM using the capacitor that uses the capacitor insulating film of the invention.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

Elemental ratio of each element of the STO film is not limited to a chemical formula SrTiO₃ that means a stoichiometric ratio of Sr:Ti:O equals to 1:1:3, but may be any non-stoichiometric ratio as long as the STO film includes three elements, a strontium (Sr), a titanium (Ti), and an oxygen (O).

### First Preferred Embodiment

FIG. 1 is a fragmentary cross sectional elevation view illustrating a capacitor in accordance with a first preferred embodiment of the present invention. The capacitor is formed by disposing a crystal STO film 3 between electrodes 1 and 2 that are made of a ruthenium (Ru). The STO film 3 is formed so that the spectrum intensity ratio (200)/(111) of the STO film 3 is in the range of 1.0 to 2.3, where the spectrum intensity ratio (200)/(111) of the STO film 3 is the ratio of the spectrum intensity of (200) crystal face of the STO film 3 to the spectrum intensity of (111) crystal face of the STO film 3, and each of the spectrum intensities of the (200) crystal face and (111) crystal face is measured by the X-ray diffraction method.

A material of the electrodes 1 and 2 is not limited to the ruthenium, but may be other metal film of high melting point such as a platinum (Pt) film or a titanium nitride (TiN) film, or a laminated film made of a plurality of metal films of high melting point.

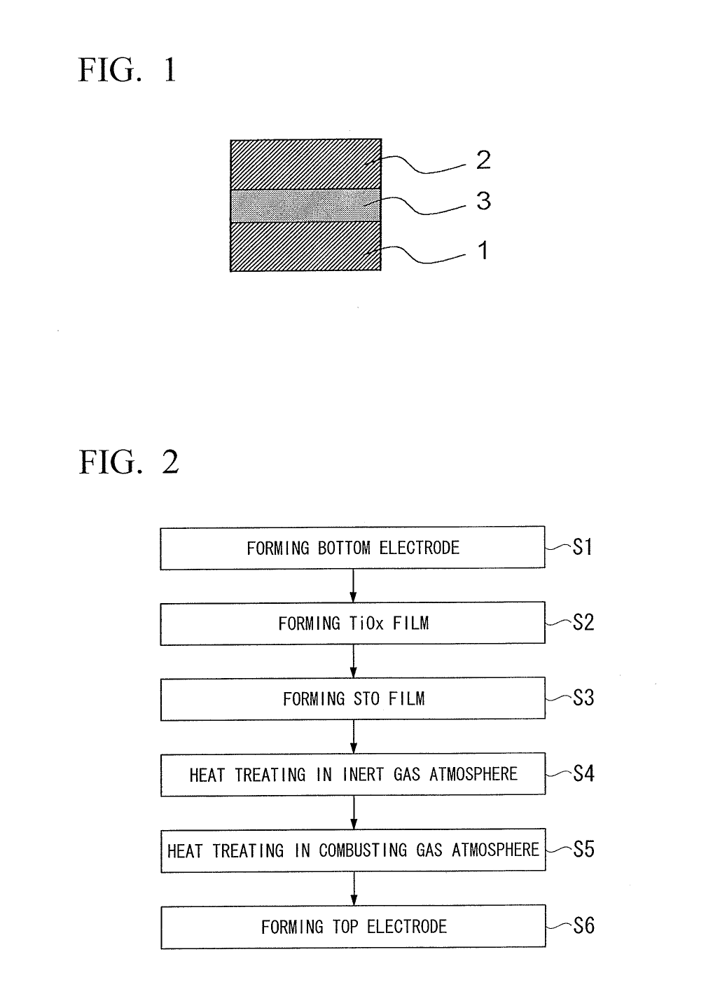

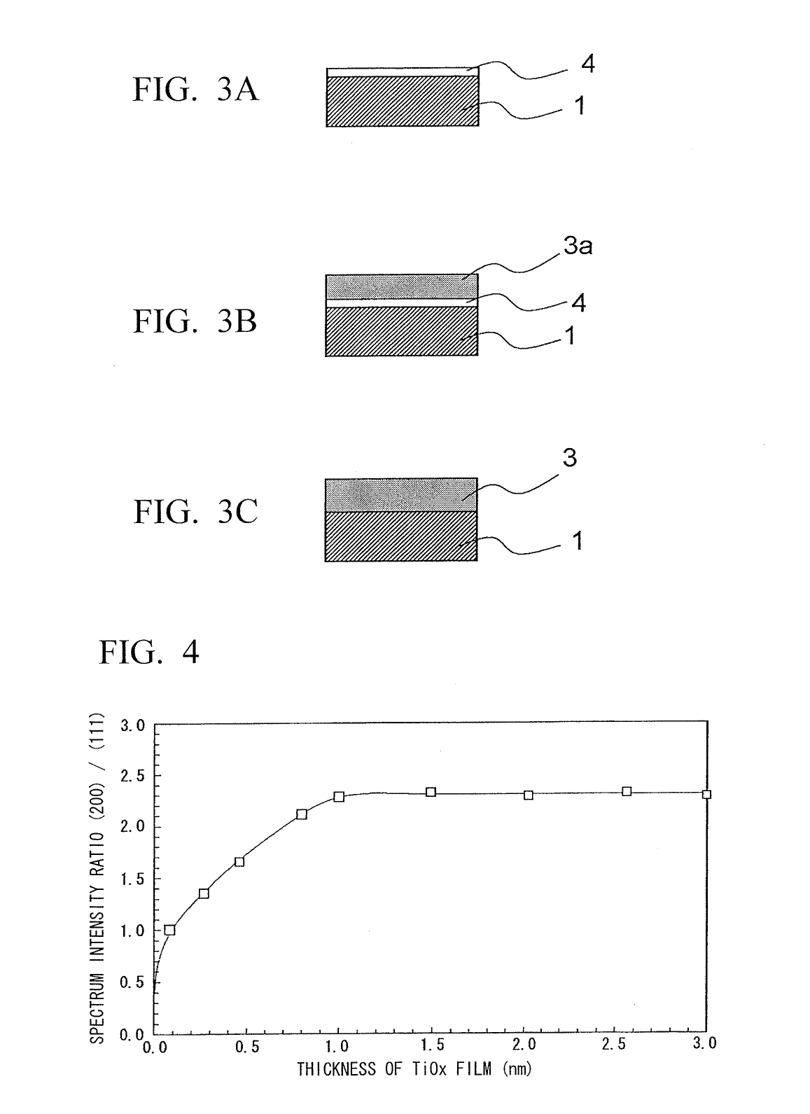

A method forming the capacitor insulating film and the capacitor will be described. FIG. 2 is a flow chart illustrating processes of forming the capacitor of FIG. 1. FIGS. 3A, 3B and 3C are fragmentary cross sectional elevation views illustrating the capacitor of each of the forming processes of FIG. 2. The capacitor is formed by performing each of the processes S1, . . . , S6 in series.

[Process S1]

As illustrated in FIG. 3A, the bottom electrode 1 is formed by a patterning of a ruthenium film formed on a semiconductor substrate (that is not described in the figure).

[Process S2]

The titanium oxide (TiOx, where x is a positive number) film 4 is formed on the bottom electrode 1 by an Atomic Layer Deposition method, hereinafter referred to as an ALD method. Titanium (Ti) is oxidized by a cycle of heating the semiconductor substrate at 300° C., supplying a titanium (Ti) material gas for a predetermined time that is about 10 seconds, and supplying an ozone (O₃) that is a combusting gas for a predetermined time. This cycle is a cycle of the ALD method, and by repeating the cycle for several times, the titanium oxide (TiOx) film 4 is formed with thickness in the range of 0.1 to 2.0 nm. The titanium (Ti) material gas may be a known material gas such as a tetrakis isopropoxy titanium (Ti(OCH(CH₃)₂)₄), a tetrakis (2-methoxy-1-methyl-1-propoxo) titanium (Ti(MMP)₄), a TiO(tmhd)₂ where tmhd is 2,2,6,6-tetramethylheptane-3,5-dione, and a Ti(depd)(tmhd)₂ where depd is diethylpentanediol, but not limited to these material gases. The combusting gas may be a water vapor (H₂O) or an oxygen (O₂) excited with plasma other than the ozone (O₃).

[Process S3]

As illustrated in FIG. 3B, the amorphous STO film 3a is formed on the titanium oxide (TiOx) film 4 by the ALD method. A cycle of the ALD method consists of an oxidation reaction of a strontium (Sr) and an oxidation reaction of the titanium (Ti). The oxidation reaction of a strontium (Sr) is performed by heating the semiconductor substrate at 300° C., supplying the strontium (Sr) material gas for a predetermined time that is about 10 seconds, and supplying the ozone (O₃) that is the combusting gas for a predetermined time. Then the oxidation reaction of the titanium (Ti) is performed by supplying the titanium (Ti) material gas for a predetermined time that is about 10 seconds, and supplying the ozone (O₃) gas that is a combusting gas for a predetermined time. By repeating the cycle for several times, the STO film 3a is formed with an intended thickness. The thickness of the STO film 3a may be thicker than the titanium oxide (TiOx) film 4 formed in the process S2, and preferably thicker than 1 nm. The strontium (Sr) material gas may be a bis (pentamethylcyclopentadienyl) strontium (Sr(C₅(CH₃)₅)₂), a Sr(DPM)₂ where DPM is dipivaloylmethanate, a Sr(METHD)₂ where METHD is methoxy-ethoxy-tetramethyl-heptanedionate, a Sr(OC₂H₅)₂, a Sr(OC₃H₇)₂, and a Sr(HfA)₂ where HfA is hexafluoroacetylacetonate, but not limited to these material gases. The titanium (Ti) material gas can be the same material gas described in the process S2 of forming the titanium oxide (TiOx) film.

In a conventional sequence of the ALD method, to fabricate the STO film of high dielectric constant, the strontium oxide film of high dielectric constant is formed first, and then the titanium oxide film and the strontium oxide film are formed alternately. The thickness of the titanium oxide film per one cycle of the conventional sequence of the ALD method is less than 0.1 nm. Even if the sequence of the ALD method is performed in reverse, the thickness of the formed titanium oxide film is not so thick as the present invention.

[Process S4]

As illustrated in FIG. 3C, a crystal STO film 3 is formed by heat treatment for about one minutes in an inert gas atmosphere such as nitrogen (N₂) or argon (Ar) at about 600° C., that is a Rapid Thermal Annealing method, hereinafter referred to as a RTA method. The crystallization of the amorphous STO film proceeds when the temperature of the heat treatment of this process is not less than 500° C. Diffusion of the oxygen from the STO film to the bottom electrode material is suppressed and the lowering of the dielectric constant can be suppressed when the temperature of the heat treatment of the process is not more than 700° C.

[Process S5]

Heat treatment at about 450° C. in a combusting gas atmosphere is performed to transform the STO film 3 to a more dense film. A gas including the oxygen (O₂) can be used as the combusting gas. The heat treatment is preferable to be performed in a short time by the RTA method. The temperature of the heat treatment is preferable to be in the range of 400° C. to 500° C.

By performing the heat treatment, the boundary between the titanium oxide (TiOx) film 4 formed in the process S2 and the STO film 3a becomes unclear, and the titanium oxide (TiOx) film 4 and the STO film 3a becomes an integrated STO film 3. The process S5 that is the oxidizing heat treatment can be omitted depending on the electric characteristic needed by the STO film to be formed finally.

[Process S6]

As illustrated in FIG. 1, a top electrode 2 is formed on the STO film 3 using a ruthenium (Ru) film. By the processes S1, S2, . . . , S6, the capacitor is formed.

In the present invention, the orientation of the crystal face of the finally formed crystal STO film can be controlled by forming the titanium oxide film before forming the amorphous STO film.

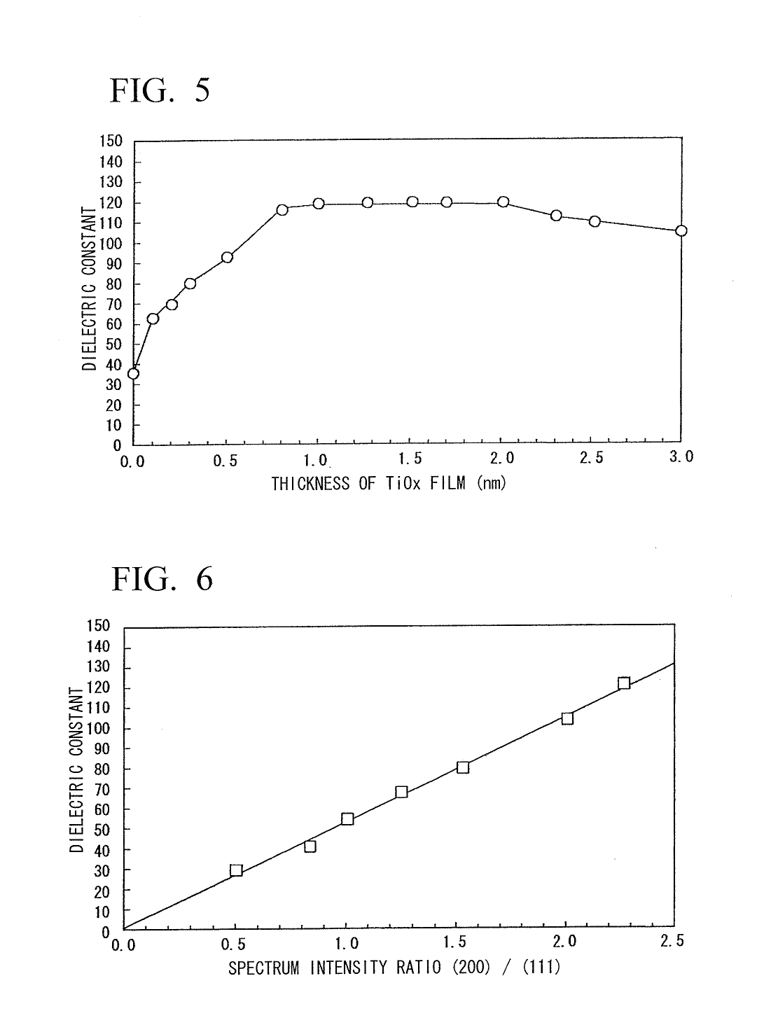

FIG. 4 is a chart indicating the relationship between the spectrum intensity ratio (200)/(111) of the STO film and the thickness of the titanium oxide (TiOx) film formed in the process S2, where the spectrum intensity ratio (200)/(111) of the STO film is the ratio of the spectrum intensity of (200) crystal face of the STO film to the spectrum intensity of (111) crystal face of the STO film, and each of the spectrum intensities of (200) crystal face and (111) crystal face is measured by the X-ray diffraction method. In the measurements illustrated in FIG. 4, FIG. 5, and FIG. 6, the thickness of the amorphous STO film is 10 nm, and the thickness of the titanium oxide (TiOx) film formed in the process S2 is changed.

When the thickness of the titanium oxide (TiOx) film is less than 1 nm, the spectrum intensity ratio (200)/(111) of the STO film increases as the thickness of the titanium oxide (TiOx) film increases. When the thickness of the titanium oxide (TiOx) film is more than 1 nm, the spectrum intensity ratio (200)/(111) of the STO film is constant. By forming the titanium oxide (TiOx) film first, the orientation of (200) crystal face of the STO film increases and the orientation of (111) crystal face of the STO film is suppressed. As is obvious from FIG. 4, the spectrum intensity ratio (200)/(111) of the STO film can be any value in the range of 1.0 to 2.3 by adjusting the thickness of the first formed titanium oxide (TiOx) film in the range of 0.1 nm to 1 nm.

FIG. 5 is a chart indicating the relationship between the dielectric constant of the formed STO film and the thickness of the titanium oxide (TiOx) film. The vertical axis of FIG. 5 indicates the dielectric constant of the STO film, and the horizontal axis of FIG. 5 indicates the thickness of the titanium oxide (TiOx) film. When the thickness of the titanium oxide (TiOx) film is less than about 1 nm, the dielectric constant of the STO film increases as the thickness of the titanium oxide (TiOx) film increases. When the thickness of the titanium oxide (TiOx) film is more than about 2 nm, the dielectric constant of the STO film gradually decreases as the thickness of the titanium oxide (TiOx) film increases. It is estimated that the dielectric constant of the finally formed STO film decreases as the mixture fraction of the titanium oxide (TiOx) which dielectric constant is less than that of the strontium titanate (STO) increases. As a result, the thickness of the titanium oxide (TiOx) film is preferable to be not more than 2 nm.

FIG. 6 is a chart indicating the relationship between the dielectric constant of the formed STO film and the spectrum intensity ratio (200)/(111) of the STO film. The vertical axis of FIG. 6 indicates the dielectric constant of the formed STO film, and the horizontal axis of FIG. 6 indicates the spectrum intensity ratio (200)/(111) of the STO film. The dielectric constant of the STO film increases by suppressing the orientation of (111) crystal face of the STO film and increasing the orientation of (200) crystal face of the STO film. When the spectrum intensity ratio (200)/(111) of the STO film is maximized to be 2.3, the dielectric constant of the STO film is about 120.

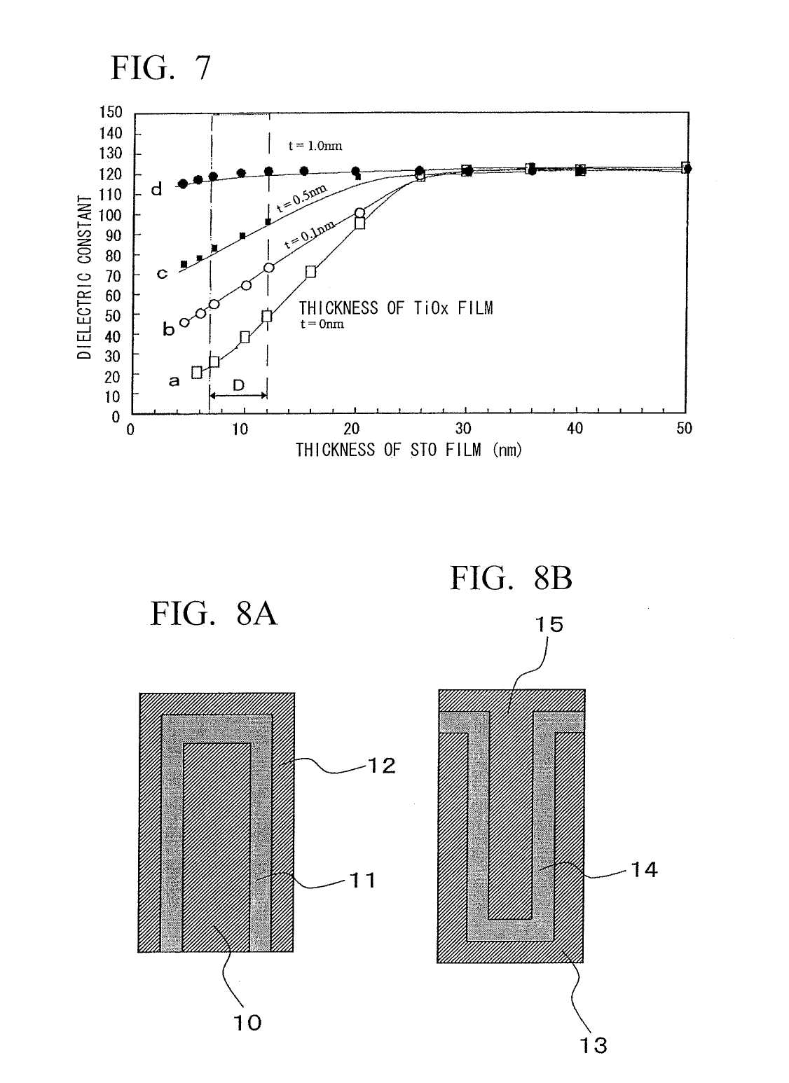

FIG. 7 is a chart indicating the relationship between the dielectric constant of the formed STO film and the thickness of the STO film. The vertical axis of FIG. 7 indicates the dielectric constant of the STO film, and the horizontal axis of FIG. 7 indicates the thickness of the STO film. Reference t is a parameter indicating the thickness of the titanium oxide (TiOx) film. The line a represents when the thickness t of the titanium oxide (TiOx) film equals to 0 nm that means the titanium oxide (TiOx) film is not formed at first. The line a shows that the dielectric constant of the STO film dramatically decreases when the thickness of the STO film becomes less than about 25 nm. The lines b, c and d represent when the titanium oxide (TiOx) film is formed at first. Each of the lines b, c and d shows that the decrease of the dielectric constant of the STO film is suppressed even if the thickness of the STO film becomes less than about 25 nm. As a result, the present invention is effective when the STO film is not less than 1 nm and not more than 25 nm.

In general, the real thickness of the capacitor insulating film is about 10 nm when the capacitor is disposed on the semiconductor device such as the DRAM. FIG. 7 shows that the dielectric constant of the capacitor insulating film of the present invention is drastically improved in the area indicated by an arrow D in FIG. 7 that is the area of the thickness of the STO film in the range of 7 nm to 12 nm and includes when the real thickness of the capacitor insulating film is 10 nm. Generation of a tunneling current can be effectively prevented when the thickness of the capacitor insulating film is not less than 7 nm. The capacitor insulating film of the present invention can be applied to the DRAM in the generation of 40-nm-class process technology when the thickness of the capacitor insulating film is not more than 12 nm.

As is described above, the spectrum intensity ratio (200)/(111) of the STO film measured by the X-ray diffraction method can be made in the range of 1.0 to 2.3 by forming the titanium oxide (TiOx) film at first when forming the capacitor insulating film using the strontium titanate (STO). As a result, the decrease of the dielectric constant can be suppressed even if the thickness of the STO film is about 10 nm, and the capacitor of large capacity can be easily fabricated.

In a conventional art, when the bottom electrode contains the ruthenium (Ru) as a major ingredient and the STO film is formed directly on the bottom electrode, a damage may occur on the surface of the ruthenium (Ru) in performing the oxidizing reaction of the strontium (Sr) in the process S3 of FIG. 2. The damage causes a defect such as a hillock defect, a blister defect, etc. So it is necessary to raise the temperature when forming the STO film, and it is difficult to form the dense STO film.

In the present invention, the titanium oxide (TiOx) film is formed before the STO film is formed in the process S2, and the damage to the surface of the film containing the ruthenium (Ru) as a major ingredient can be suppressed. Then the STO film can be formed under high temperature condition as about 300° C. and the dense STO film can be easily formed. The leakage of the capacitor insulating film can be decreased easily in comparison with the conventional method in which the titanium oxide (TiOx) film is not formed.

### Second Preferred Embodiment

The capacitor that uses the capacitor insulating film of the present invention can be applicable not only to the case when the electrode has a two-dimensional structure described in the first embodiment but also to the case when the electrode has a three-dimensional structure.

The capacitor having three-dimensional structure will be described by referring FIGS. 8A and 8B.

FIG. 8A is a fragmentary vertical cross-sectional view illustrating the capacitor of a circular cylindrical shape that is a pillar shape. The capacitor includes the bottom electrode 10, the capacitor insulating film 11 of the present invention, and the top electrode 12. The bottom electrode 10 of the capacitor is formed in the circular cylindrical shape that is the pillar shape using a metal with a high melting point such as the ruthenium (Ru). The capacitor insulating film 11 is the STO film that is formed so as to cover the top surface and the side surface of the bottom electrode 10 by the above described method. Even if the electrode has three-dimensional structure, the STO film can be formed with uniform thickness on the surface of the electrode by the ALD method and by adjusting the time of supplying the material gas and the combusting gas. The top electrode 12 is formed to cover the surface of the capacitor insulating film 11 using the metal with high melting point such as the ruthenium (Ru).

FIG. 8B is a fragmentary vertical cross-sectional view illustrating the capacitor of a hollow cylinder shape that is a cylinder shape. The capacitor includes the bottom electrode 13, the capacitor insulating film 14 of the present invention, and the top electrode 15. The bottom electrode 13 of the capacitor is formed in the hollow cylinder shape using the metal with high melting point such as the ruthenium (Ru). The capacitor insulating film 14 is the STO film that is formed so as to cover the top surface and the side surface of the bottom electrode 13 by the above described method. The top electrode 15 is formed to cover the surface of the capacitor insulating film 14 using the metal with high melting point such as the ruthenium (Ru).

As is described above, the capacitor with large capacity in the same area can be formed when the electrode of the capacitor has the three-dimensional structure described in FIGS. 8A and 8B.

### Third Preferred Embodiment

The third embodiment that applies the capacitor insulating film of the present invention to the capacitor in the memory cell of the DRAM will be described. The third embodiment is an example of the semiconductor device using the capacitor insulating film of the present invention.

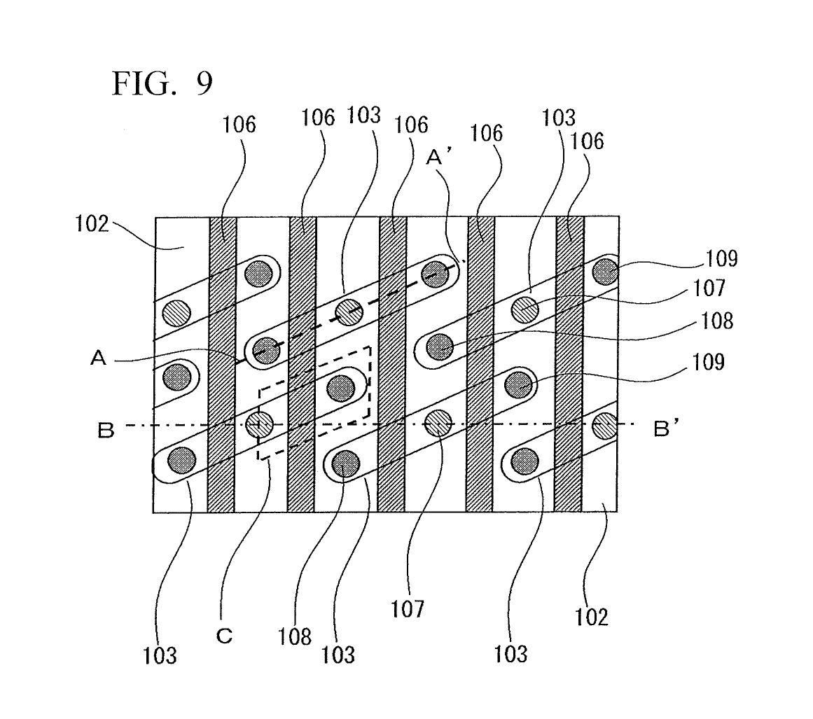

FIG. 9 is a fragmentary plain view illustrating the memory cell of the DRAM. Only a part of the memory cell is illustrated in FIG. 9 for description.

A plurality of active regions 103 are disposed on a semiconductor substrate in a regular cycle. The semiconductor substrate is not illustrated in the figure. The plurality of active regions 103 are districted by a plurality of device isolation regions 102. Each of the device isolation regions 102 is formed by embedding an insulating film such as a silicon dioxide film in the semiconductor substrate using a known method. A plurality of gate electrodes 106 are disposed across the plurality of active regions 103. Each of the plurality of gate electrodes 106 behaves as a word line of the DRAM. An n-type diffused layer region is formed in a part of the plurality of active regions 103 that is not covered with the plurality of gate electrodes 106 by ion-implanting an impurity such as phosphorus. The n-type diffused layer region works as a source and a drain region of a MOS transistor.

A part enclosed by a broken line C of FIG. 9 forms one of the MOS transistors. A contact plug 107 is disposed on the center region of the active region 103, and contacts the n-type diffused layer region on the surface of the active regions 103. A contact plug 108 is disposed on one side of the active region 103, and a contact plug 109 is disposed on the other side of the active region 103. The contact plugs 108 and 109 contact the n-type diffused layer region on the surface of the active regions 103. The contact plugs 107, 108 and 109 have different reference numbers for illustrative purposes, but can be formed simultaneously when fabricated.

In the layout of FIG. 9, each of the contact plugs 107 is disposed so as to be shared by two contacting transistors for the purpose of disposing the memory cells in high density.

A plurality of wiring layers, though not illustrated in the figure, are formed in the direction illustrated as a B-B′ line so as to contact the contact plug 107 and to intersect the gate electrode 106 at right angle in the fabricating process of later. Each of the plurality of wiring layers works as a bit line of the DRAM. Each of the contact plugs 108 and 109 is connected to the capacitor that is not illustrated in the figure and is formed using the capacitor insulating film of the present invention.

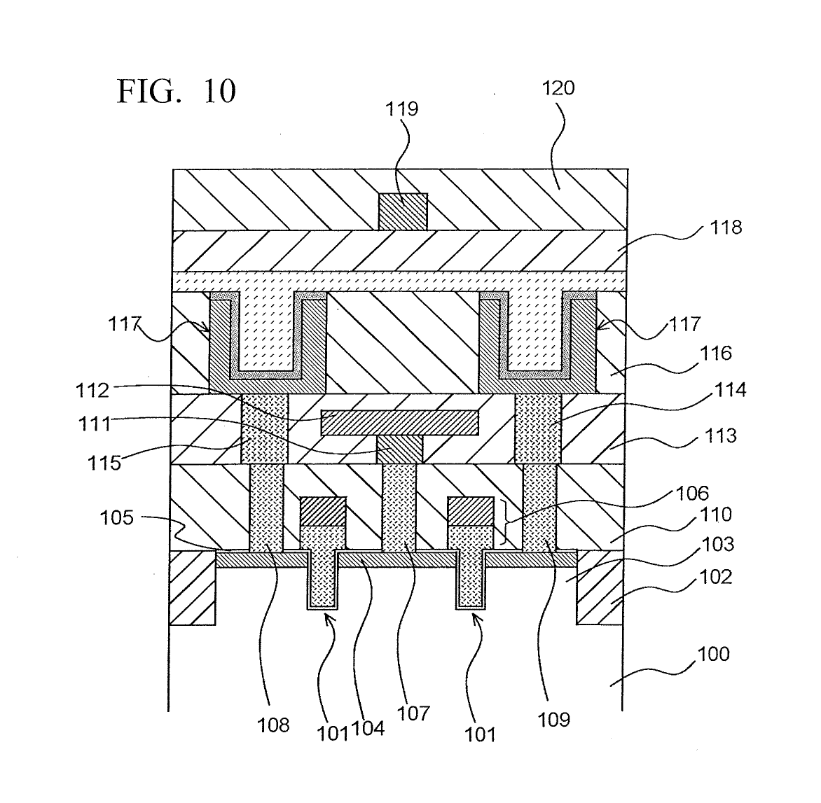

FIG. 10 is a cross sectional view illustrating the memory cell of the completed DRAM using the capacitor insulating film of the present invention. FIG. 10 corresponds to a view taken along an A-A′ line of FIG. 9. The memory cell includes the semiconductor substrate 100, the MOS transistors 101, the device isolation region 102, the active region 103, an n-type diffused layer region 104, a gate insulating film 105, the gate electrode 106, contact plugs 107, 108, 109, 111, 114 and 115, interlayer insulating films 110, 113, 116 and 118, wiring layers 112 and 119, a capacitor 117 and a surface protection film 120. The semiconductor substrate 100 is made of p-type silicon. The MOS transistor 101 includes a thin gate electrode. The gate electrode 106 works as a word line. The n-type diffused layer region 104 is formed on the surface of the active region 103, and contact the contact plugs 107, 108, and 109. Polycrystalline silicon including phosphorus can be used as a material of the contact plugs 107, 108, and 109. The interlayer insulating film 110 is formed on the MOS transistor 101. The contact plug 107 is connected to the wiring layer 112 through the contact plug 111. The wiring layer 112 works as a bit line. Tungsten can be used as the material of the wiring layer 112. The contact plugs 108 and 109 are respectively connected to the capacitor 117 through the corresponding contact plugs 114 and 115. The capacitor 117 is formed using the capacitor insulating film of the present invention. In this embodiment, the capacitor has the hollow cylinder shape of FIG. 8B, but can have another shape.

The interlayer insulating films 113, 116 and 118 are disposed for insulation between wirings. The wiring layer 119 is made of aluminum or copper and formed on the top side of the memory cell.

When the MOS transistor 101 turns ON, whether the capacitor 117 is charged or not can be judged through the wiring layer 112 that is the bit line, and the MOS transistor 101 acts as the memory cell of the DRAM that can store information.

The capacitor in the memory cell of the DRAM needs to have a large capacitor and to have a small amount of leakage.

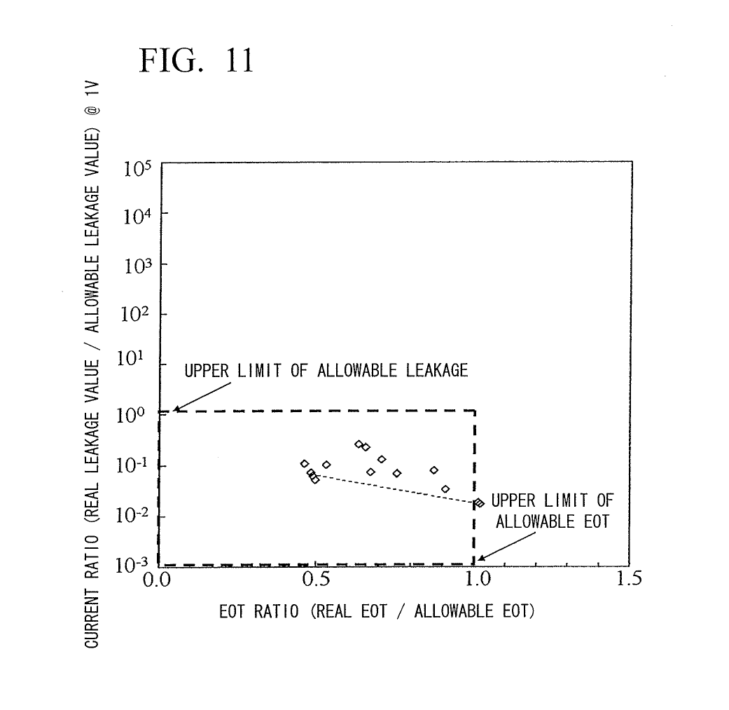

FIG. 11 is a chart indicating the relationship between the thickness of the capacitor insulating film and the leakage value and the capacity value of the capacitor using the capacitor insulating film of the present invention. The horizontal axis of FIG. 11 indicates the result of measuring an Equivalent Oxide Thickness, hereinafter referred to as an EOT, of the capacitor insulating film, and the indicated value is normalized by the value of the EOT needed by the DRAM in the generation of 40-nm-class process technology. The vertical axis of FIG. 11 indicates the result measuring the leakage value when the applied potential equals to one voltage, and the indicated value is normalized by the value of the leakage needed by the DRAM in the generation of 40-nm-class process technology.

As illustrated in FIG. 11, the capacitor which leakage value and EOT value are within the allowable range can be formed by using the capacitor insulating film of the present invention. The allowable range is illustrated in FIG. 11 as the area surrounded by the broken line.

By using the capacitor insulating film of the present invention, the memory cell that has a superior charge retention property or a refresh property can be easily fabricated, and high-performance DRAM can be easily fabricated.

The capacitor insulating film of the present invention can be applied to devices other than the memory cell of the DRAM. For example, the capacitor insulating film of the present invention can be applied to a general semiconductor device such as a logic device that does not include the memory cell as long as the semiconductor device uses the capacitor.

It is apparent that the present invention is not limited to the above embodiments, but may be modified and changed without departing from the scope and spirit of the invention.

What is claimed is:

1. A method of fabricating a capacitor insulating film, the method comprising:
forming a titanium oxide film;
forming an amorphous strontium titanate film on the titanium oxide film; and
forming a crystallized film that contains strontium, titanium and oxygen by carrying out a heat treatment in an inert gas atmosphere,
wherein the crystallized film has a crystal structure that a ratio of a spectrum intensity of (200) crystal face of the capacitor insulating film to a spectrum intensity of (111) crystal face of the capacitor insulating film is in the range of 1.0 to 2.3, each of the spectrum intensities of (200) crystal face and (111) crystal face is measured by an X-ray diffraction method.

2. The method according to claim 1, wherein the ratio of the spectrum intensity of (200) crystal face to the spectrum intensity of (111) crystal face varies in the range of 1.0 to 2.3 by changing a thickness of the titanium oxide film in the range of 0.1 nm to 1 nm.

3. The method according to claim 1, wherein forming the titanium oxide film and forming the amorphous strontium titanate film are each performed by an atomic layer deposition method.

4. The method according to claim 1, wherein a thickness of the capacitor insulating film is in the range of 7 nm to 12 nm.

5. The method according to claim 1, further comprising:
carrying out a further heat treatment to the crystallized film in a combusting gas atmosphere after forming the crystallized film.

6. The method according to claim 5, wherein the further heat treatment is performed at a temperature in the range of 400° C. to 500° C.

7. The method according to claim 1, wherein the heat treatment in the inert gas atmosphere is performed at a temperature in the range of 500° C. to 700° C.

8. The method according to claim 1, wherein the titanium oxide film is formed on a bottom electrode which contains ruthenium as a major component.

9. A method comprising forming an insulating film between first and second electrodes and interposing a titanium oxide film between the first electrode and the insulating film, the titanium oxide film being in direct contact with the first electrode.

10. The method according to claim 9, wherein each of the insulating film and the titanium oxide film is formed by an atomic layer deposition method.

11. The method according to claim 9, wherein the insulating film comprises strontium, titanium and oxygen.

12. The method according to claim 9, wherein a thickness of the titanium oxide film is in a range of 0.1 nm to 2 nm.

13. The method according to claim 9, wherein a thickness of the insulating film is in a range of 1 nm to 25 nm.

14. A method comprising:
forming a first conductive layer serving as a first electrode of a capacitor;
forming a first film on the first conductive layer in direct contact therewith, the first film consisting of titanium and oxygen;
forming a second film on the first layer, the second film being different in material than the first film and representing an insulating characteristic; and
forming a second conductive layer serving as a second electrode of the capacitor.

15. The method according to claim 14, wherein each of the first film and the second film is formed by an atomic layer deposition method.

16. The method according to claim 14, wherein the second film comprises strontium, titanium and oxygen.

17. The method according to claim 14, wherein a thickness of the first film is in a range of 0.1 nm to 2 nm.

18. The method according to claim 14, wherein a thickness of the first film is in a range of 1 nm to 25 nm.

19. The method according to claim 14, wherein the first conductive layer, the first film, the second film and the second conductive layer work as the capacitor in a transistor of a memory device, the capacitor being contact with the transistor via the first or second conductive layer.
